(19) United States
(12) Patent Application Publication
(10) Pub. No.: US 2024/0288787 A1
(43) Pub. Date: Aug. 29, 2024

(54) MEASURING METHOD OF MEASURING SUBSTRATE BY CAPTURING IMAGES OF MARKS THEREON

(71) Applicant: CANON KABUSHIKI KAISHA, Tokyo (JP)

(72) Inventors: WATARU YAMAGUCHI, Tochigi (JP); SHINICHIRO HIRAI, Saitama (JP); TAKASHI KURIHARA, Tochigi (JP)

(21) Appl. No.: 18/585,271

(22) Filed: Feb. 23, 2024

(30) Foreign Application Priority Data
Feb. 28, 2023 (JP) 2023-030137

(51) Int. Cl. G03F 9/00

(52) U.S. Cl. CPC G03F 9/7088; G03F 9/7084; G03F 9/7092

(57) ABSTRACT

A measuring method of measuring a substrate includes capturing images of a plurality of marks provided on the substrate, and processing a plurality of evaluation values while giving weights to the plurality of evaluation values respectively obtained from the images of the plurality of marks captured in the capturing, thereby acquiring information indicating a state of the substrate. The plurality of marks include at least two marks simultaneously captured in the capturing.

### BACKGROUND OF THE INVENTION

### Field of the Invention

The present invention relates to a measuring method of measuring a substrate by capturing images of marks thereon.

### Description of the Related Art

In a lithography apparatus such as an exposure apparatus used in a lithography process, importance is placed on the alignment accuracy between a shot region on a substrate and an original and the overlay accuracy between different layers on the substrate. As a method for improving the alignment accuracy and the overlay accuracy, there is a method of selecting the measurement mark or measurement condition which is less susceptible to degradation of measurement accuracy caused by a change in substrate characteristic. With this method, it is possible to maximize the intensity and quality of a detection signal from the measurement mark, and implement measurement with high accuracy.

Japanese Patent No. 3994223 describes a method of deciding the detection range in image processing of overlay measurement marks in order to improve overlay measurement accuracy. The detection range and overlay error are obtained from the acquired images of the overlay measurement marks, thereby deciding the detection range with the minimum overlay error.

If the shape or characteristic of a mark formed on a substrate changes, the intensity and quality of a detection signal from the mark may decrease, and this can lead to degradation of measurement accuracy.

### SUMMARY OF THE INVENTION

The present invention provides a technique advantageous in implementing high measurement accuracy.

A first aspect of the present invention provides a measuring method of measuring a substrate, comprising: capturing images of a plurality of marks provided on the substrate; and processing a plurality of evaluation values while giving weights to the plurality of evaluation values respectively obtained from the images of the plurality of marks captured in the capturing, thereby acquiring information indicating a state of the substrate, wherein the plurality of marks include at least two marks simultaneously captured in the capturing.

A second aspect of the present invention provides a pattern forming method of forming a pattern on a substrate, comprising: measuring the substrate by a measuring method defined as the first aspect; and transferring a pattern to the substrate based on a result obtained in the measuring.

A third aspect of the present invention provides an article manufacturing method including: forming a pattern on a substrate in accordance with a pattern forming method defined as the second aspect; and processing the substrate with the pattern formed thereon in the forming, thereby obtaining an article.

A fourth aspect of the present invention provides a measurement apparatus for measuring a substrate, comprising: an image capturing device configured to capture images of a plurality of marks provided on the substrate; and a processor configured to process a plurality of evaluation values while giving weights to the plurality of evaluation values respectively obtained from the images of the plurality of marks captured by the image capturing device, thereby acquiring information indicating a state of the substrate, wherein the plurality of marks include at least two marks simultaneously captured by the image capturing device.

A fifth aspect of the present invention provides a lithography apparatus comprising: a measurement apparatus defined as the fourth aspect; and a system configured to align a substrate and an original based on a result obtained by the measurement apparatus, and transfer a pattern of the original to the substrate.

A sixth aspect of the present invention provides an article manufacturing method comprising: forming a pattern on a substrate by using a lithography apparatus defined as the fifth aspect; and processing the substrate with the pattern formed thereon in the forming, thereby obtaining an article.

A seventh aspect of the present invention provide a computer readable medium storing a program for causing a computer to execute a process of evaluating a substrate, wherein the process includes acquiring information indicating a state of the substrate by processing a plurality of evaluation values while giving weights to the plurality of evaluation values respectively obtained from images of the plurality of marks provided on the substrate, wherein the plurality of marks include at least two marks captured simultaneously.

Further features of the present invention will become apparent from the following description of exemplary embodiments with reference to the attached drawings.

### BRIEF DESCRIPTION OF THE DRAWINGS

FIGS. 1A and 1B are views showing the arrangement of a measurement apparatus according to the first embodiment;

FIGS. 2A and 2B are views for explaining a specific measurement process in the measurement apparatus according to the first embodiment;

FIGS. 3A and 3B are views for explaining a specific measurement process in the measurement apparatus according to the first embodiment;

FIG. 4 is a flowchart for explaining a measurement sequence in the measurement apparatus according to the first embodiment;

FIG. 5 is a view for explaining a specific measurement process in the measurement apparatus according to the first embodiment;

FIG. 6 is a flowchart for explaining a measurement sequence for weighting in the measurement apparatus according to the first embodiment;

FIGS. 7A to 7E are views for explaining a specific measurement process in the measurement apparatus according to the first embodiment;

FIGS. 8A and 8B are views for explaining a specific measurement process in the measurement apparatus according to the first embodiment;

FIG. 9 is a flowchart for explaining a measurement sequence in a measurement apparatus according to the second embodiment;

FIG. 10 is a flowchart for explaining a measurement sequence for weighting in the measurement apparatus according to the second embodiment;

FIGS. 11A and 11B are views for explaining a specific measurement process in the measurement apparatus according to the second embodiment;

FIG. 12 is a view for explaining the arrangement of an exposure apparatus according to the third embodiment; and

FIG. 13 is a flowchart for explaining the sequence of an exposure process of the exposure apparatus according to the third embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### First Embodiment

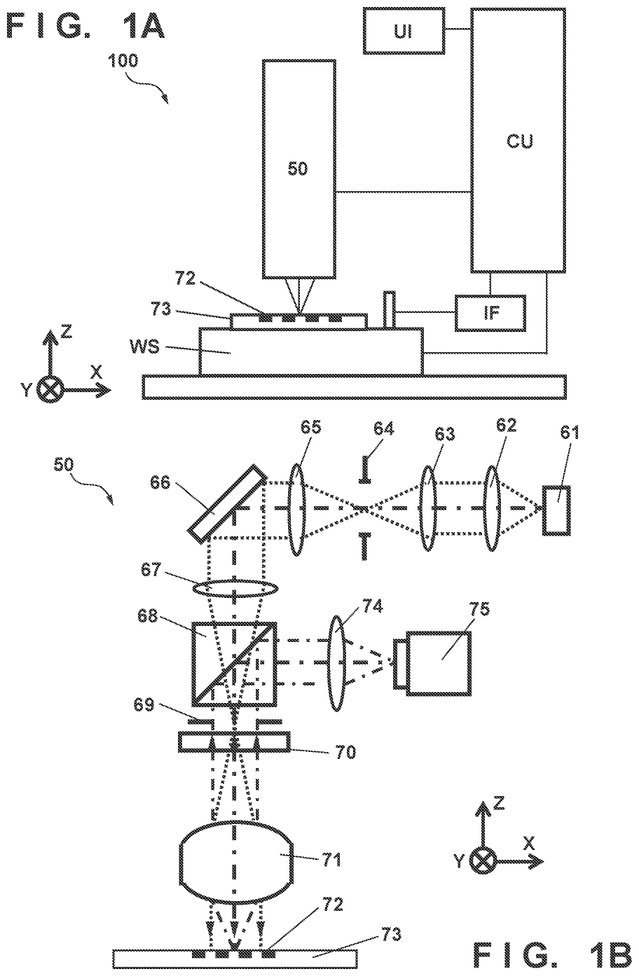

FIG. 1A is a schematic view showing the arrangement of a measurement apparatus 100 according to one aspect of the present disclosure. The measurement apparatus 100 can be configured as a measurement apparatus that measures a mark formed on a substrate 73, for example, a measurement apparatus that measures at least one of the position, quality, state, and characteristic of the mark. The measurement apparatus 100 can include, for example, a substrate stage WS that holds the substrate 73, an image capturing device 50 that captures the image of a mark, a control unit CU, and an interface UI. Here, the substrate 73 is, for example, a substrate used to manufacture a device, such as a semiconductor device or a display device, or an article. More specifically, the substrate 73 is a wafer, a glass substrate, or another member.

The substrate stage WS can hold the substrate 73 via a substrate chuck (not shown). The substrate stage WS is driven by a substrate driving mechanism (not shown). The substrate driving mechanism includes a linear motor or the like, and moves the substrate 73 held by the substrate stage WS by driving the substrate stage WS in in the X-axis direction, the Y-axis direction, the Z-axis direction, and the rotation directions around the respective axes. The position of the substrate stage WS is monitored by, for example, a 6-axis laser interferometer IF, and the substrate stage WS is driven to a target position under the control of the control unit CU (processor).

The control unit CU is formed by, for example, a computer (information processing apparatus) including a CPU, a memory, and the like, and comprehensively controls the respective units of the measurement apparatus 100 in accordance with a program stored or loaded in the memory. The operation of the measurement apparatus 100 can be characterized by the program. The control unit CU can calculate the position of a measurement mark 72 by processing an image capturing result of the image capturing device 50, that is, the image of the measurement mark 72 formed on the substrate 73. The control unit CU can control the operation of the measurement apparatus 100 so as to execute a measuring method of measuring the substrate. The measuring method can include an image capturing step of capturing images of a plurality of marks provided on the substrate, and a processing step of processing the images of the plurality of marks captured in the image capturing step. The processing step can include a step of acquiring information indicating the state of the substrate by processing a plurality of evaluation values while giving weights to the plurality of evaluation values respectively obtained from the images of the plurality of marks captured in the image capturing step.

The interface UI can include a display device, an input device, and the like. The user can designate, via the interface UI, the position of a shot region or the measurement mark in a shot region, which is set to the measurement target, with respect to a plurality of shot regions on the substrate 73.

With reference to FIG. 1B, an optical system of the image capturing device 50 will be exemplarily described. The image capturing device 50 can be called an alignment scope. The image capturing device 50 can include an illumination optical system that illuminates the substrate 73 using light from a light source 61, and an imaging optical system that forms, on an image capturing element 75, an image of the measurement mark 72 on the substrate 73. Light from the light source 61 is guided to an illumination aperture stop 64 via lenses 62 and 63. The light having passed through the illumination aperture stop 64 is guided to a polarization beam splitter 68 via a lens 65, a mirror 66, and a lens 67. The P-polarized light transmitted through the beam split plane of the polarization beam splitter 68 passes through an aperture stop 69. After that, the light is converted into circularly polarized light by a λ/4 plate 70 and Koehler-illuminates, via an objective lens 71, the measurement mark 72 formed on the substrate 73.

The light that Koehler-illuminates and is reflected, diffracted, and scattered by the measurement mark 72 passes through the objective lens 71 and the λ/4 plate 70, and is guided to the aperture stop 69. Here, the polarization state of the light from the measurement mark 72 becomes circular polarization that is reverse to the circular polarization of the light which Koehler-illuminates the measurement mark 72. When the light passes through the λ/4 plate 70, the light is converted from the circularly polarized light to the S-polarized light. After passing through the aperture stop 69, the S-polarized light is reflected on the beam split plane of the polarization beam splitter 68, and guided to the image capturing element 75 via a lens 74.

The illumination optical system may be provided with a light amount adjustment unit (not shown) and/or a wavelength adjustment unit (not shown). For example, when a plurality of ND filters, which have different transmittances to the light from the light source 61, are arranged so as to be switchable, and the light amount adjustment unit controls switching of the ND filters, the intensity of light illuminating the substrate 73 can be adjusted. Further, when a plurality of wavelength filters, which transmit light beams having different wavelength characteristics of the light from the light source 61, are arranged so as to be switchable, and the wavelength adjustment unit controls switching of the wavelength filters, the wavelength of light illuminating the substrate 73 can be adjusted. The wavelength adjustment unit can further include a wavelength variable element and a driving mechanism that drives the wavelength variable element. The driving mechanism includes a linear motor or the like, and can adjust the wavelength of light illuminating the measurement mark 72 by driving the wavelength variable element along a predetermined direction.

The control unit CU described above acquires the position of the measurement mark 72 based on position information of the substrate stage WS obtained by the laser interferometer IF, and a signal waveform obtained by detecting the image of the measurement mark 72. The intensity of the signal waveform can be adjusted by, for example, the light amount adjustment unit (ND filter) provided in the illumination optical system of the image capturing device 50, controlling the output of the light source 61, and controlling the accumulation time of the image capturing element 75.

In the imaging optical system of the image capturing device 50, a detection aperture stop may be formed by arranging a plurality of lenses between the polarization beam splitter 68 and the image capturing element 75. Alternatively, a plurality of aperture stops which enable setting of different numerical apertures with respect to the illumination optical system and the imaging optical system may be provided in each of the illumination aperture stop 64 and the detection aperture stop, and the plurality of aperture stops may be switchable. With this, it is possible to adjust the o value which is a coefficient representing the ratio of the numerical aperture of the illumination system and the numerical aperture of the imaging system. As a method of detecting the light from the measurement mark 72, for example, dark field detection may be used in which the aperture diameters of the illumination aperture stop 64 and the detection stop are controlled to block the 0th-order diffracted light from the measurement mark 72, thereby detecting only higher-order diffracted light and scattered light.

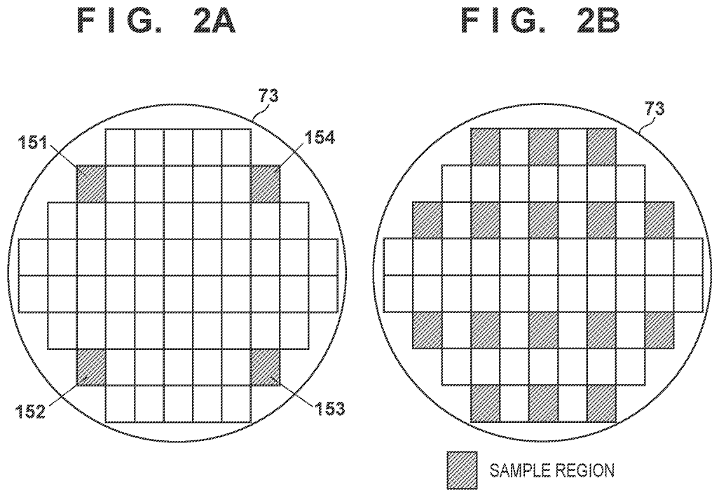

A measuring method will be described below in which, by using the measurement apparatus 100 and the image capturing device 50 described above with reference to FIGS. 1A and 1B, the substrate 73 is measured based on images obtained by simultaneously capturing at least two marks on the substrate 73. Each of FIGS. 2A and 2B is a view showing a plurality of shot regions defined on the substrate 73. Measurement of a measurement mark is performed with respect to the measurement mark provided in each sample region. The sample region means a selected shot region. The shot region can include a region where a device pattern is formed, and scribe lines near the region. FIGS. 2A and 2B show examples of selection of sample regions, and the number of sample regions and the layout of sample regions to be designated may be changed in accordance with the required substrate position measurement accuracy.

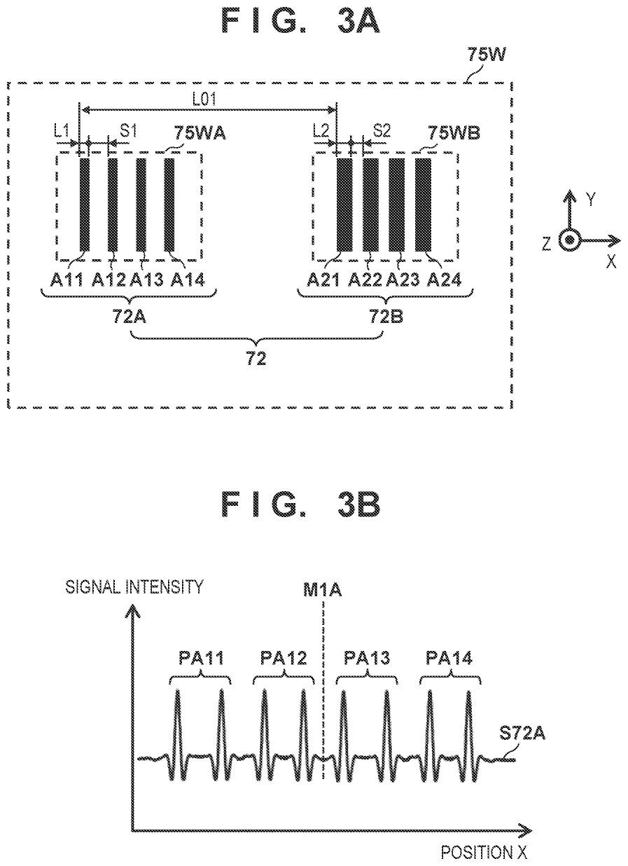

FIG. 3A is a view showing an example of the measurement mark 72 provided in the shot region on the substrate 73. Usually, X-direction position information and Y-direction position information of the measurement mark 72 are acquired. However, for the sake of descriptive simplicity, a view showing only an X mark used to measure the X-direction position will be representatively used to give a description.

The measurement mark 72 provided in the shot region or sample region can include a mark 72A formed by mark patterns A11 to A14, and a mark 72B formed by mark patterns A21 to A24. Each of the marks 72A and 72B is a line-and-space mark, and can have an arrangement in which a line portion having a length L1 or L2 and a space portion having a length S1 or S2 are periodically repeated as shown in FIG. 3A. The marks 72A and 72B can be different in the length of at least one of the line portion and the space portion. The difference between the marks 72A and 72B is not limited to the lengths of the line portion and the space portion, but may be at least one of the mark design, the number of mark patterns, the formation position in the Z direction on the substrate, and the like.

FIG. 3A exemplarily shows a measurement region 75W of the image capturing device 50. The measurement region 75W may be understood as the field of view of the image capturing device 50 or the image capturing region (effective pixel region) of the image capturing element 75. The substrate 73 can be aligned with respect to the image capturing device 50 such that at least two marks 72A and 72B in the shot region are brought into the measurement region 75W (field of view). With this, it is possible to simultaneously capture images of at least two marks 72A and 72B by the image capturing device 50 (image capturing element 75). In an example, rough measurement of the measurement mark 72 is performed and, based on a result of the rough measurement, the control unit CU can set process regions respectively corresponding to at least two marks 72A and 72B. For example, process regions 75WA and 75WB are respectively set for the marks 72A and 72B, and the control unit CU processes images of the process regions 75WA and 75WB. Thus, pieces of position information of the marks 72A and 72B can be detected.

FIG. 3B is a graph exemplarily showing a result obtained by capturing the image of the mark 72A by the image capturing element 75 and photoelectrically converting the X-direction signal intensity in the process region 75WA. S72A represents signal intensity information including peak signals PA11 to PA14 corresponding to the mark patterns A11 to A14. Each peak signal can include two peaks formed by one mark pattern. The control unit CU can calculate, based on the signal intensity information S72A, the position of the mark 72A with respect to the reference position of the image capturing element 75 as a measurement value MIA. Similarly, for the mark 72B, a measurement value M2B of the mark 72B can be calculated. The measurement value M1A is not limited to the measurement value with respect to the reference position of the image capturing element 75. For example, the position with respect to a measurement template set in advance or a design value may be used as the measurement value.

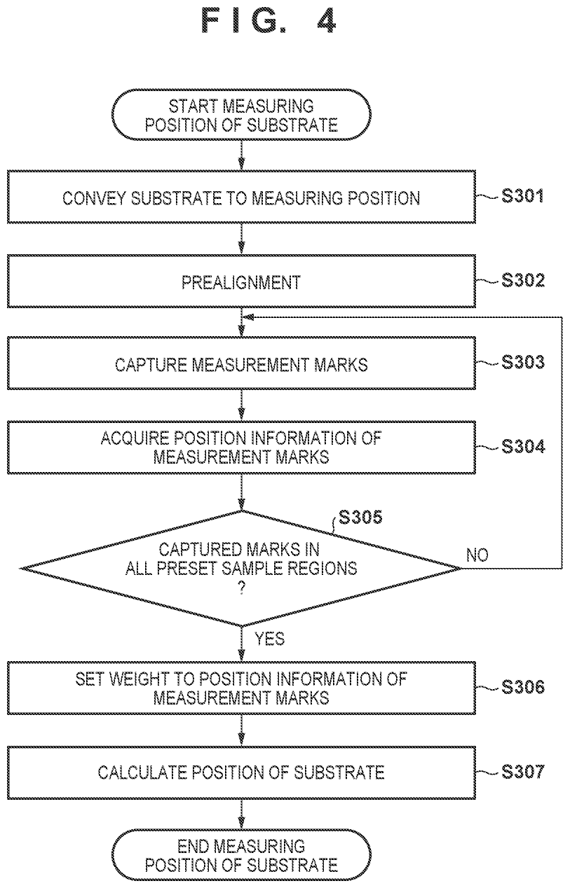

Subsequently, with reference to FIG. 4, the sequence of the measurement process (measuring method) in the first embodiment will be described. The measurement process is performed by the control unit CU comprehensively controlling the respective units of the measurement apparatus 100.

When the measurement process is started, first, under the control of the control unit CU, processing to align the relative positions of the substrate 73 and the image capturing device 50 can be executed. In step S301, the substrate 73 is conveyed into the measurement region of the image capturing device 50. In step S302, prealignment of the substrate 73 is performed to match the X-direction array direction of the plurality of shot regions on the substrate 73 with the X direction of the measurement apparatus 100.

Step S303 is an image capturing step of capturing images of a plurality of marks provided on the substrate 73 by the image capturing device 50. More specifically, in step S303, the control unit CU causes the image capturing device 50 (image capturing element 75) to capture images of at least two marks 72A and 72B in the sample region on the substrate 73. In step S304, the control unit CU processes the images (process regions 75WA and 75WB) of the marks 72A and 72B captured in step S303 to detect position information (evaluation value) of each of the marks 72A and 72B. In step S305, the control unit CU determines whether steps S303 and S304 have been performed for all the sample regions set in advance. If YES in step S305, the control unit CU advances to step S306; otherwise, the control unit CU returns to step S303.

In step S306, the control unit CU processes the position information while giving a predetermined weight to the position information (evaluation value) of each of the marks 72A and 72B in each sample region acquired in step S304. With this, the control unit CU acquires weighted position information of the measurement mark 72 including the marks 72A and 72B for each sample region. The weighted position information of the measurement mark 72 in each of the plurality of sample regions can be understood as an example of information indicating the state of the substrate 73. A weight deciding method and a weight setting method will be described later in detail.

Step S307 is a processing step of processing a plurality of evaluation values while giving weights to the plurality of evaluation values respectively obtained from the images of the plurality of marks 72A and 72B captured for each sample region in step S303, thereby acquiring information indicating the state of the substrate 73. More specifically, in step S307, the control unit CU processes a plurality of evaluation values while giving weights to the plurality of evaluation values respectively obtained from the images of the plurality of marks 72A and 72B, thereby obtaining weighted position information for each sample region on the substrate 73. Further, the control unit CU calculates the position of the substrate 73 by statistically processing pieces of weighted position information of the plurality of sample regions. Thus, the measurement sequence of the substrate 73 ends. A specific example of statistic processing can be obtaining, based on pieces of weighted position information of the measurement marks 72 in the plurality of sample regions, global alignment information, that is, information indicating the array of the plurality of shot regions on the substrate 73. The information indicating the position of the substrate 73 and the global alignment information can be understood as other examples of information indicating the state of the substrate 73.

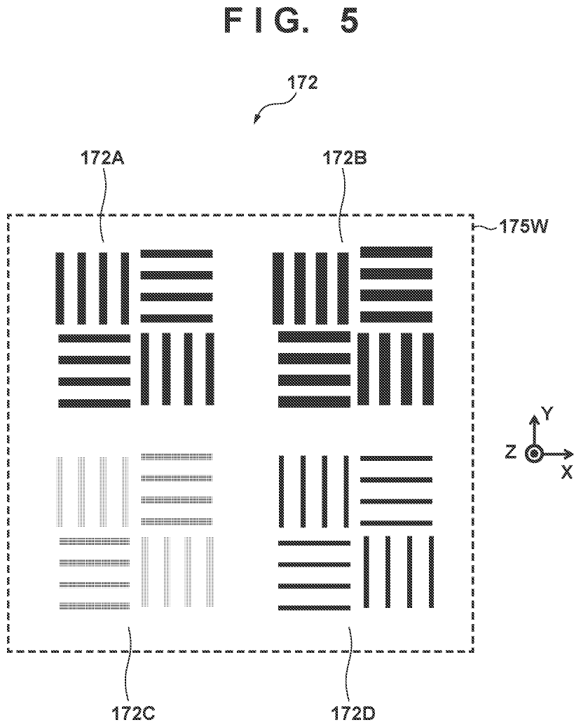

An example in which the measurement mark 72 in each sample region (each shot region) includes two marks 72A and 72B has been described above, but the measurement mark 72 in each sample region (each shot region) may include three or more marks. FIG. 5 shows an example in which a measurement mark 172 in each sample region (each shot region) includes four marks 172A to 172D, and these are brought into a measurement region 175W of the image capturing device 50. The measurement mark 172 is formed by four marks 172A to 172D, which are different from each other in at least one of the line width of pattern, the number of patterns, and the pitch of pattern. Each of the measurement marks 172A to 172D includes an X pattern (a pattern with the widthwise direction along the X direction and the longitudinal direction along the Y direction) used to measure the X-direction position, and a Y pattern (a pattern with the widthwise direction along the Y direction and the longitudinal direction along the X direction) used to measure the Y-direction position. For each mark, X-direction position information and Y-direction position information are acquired as in FIG. 3A. With this, the X-direction position and the Y-direction position may be measured for each of four marks 172A to 172D.

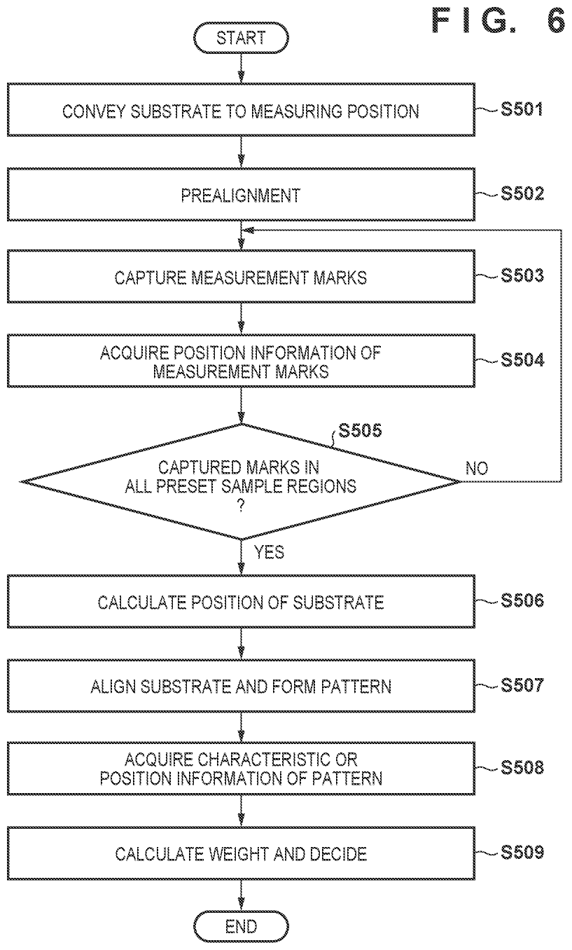

A method of deciding the weight described in step S306 of FIG. 4 will be described below. FIG. 6 is a flowchart illustrating a weight decision sequence in this embodiment. This process is preferably executed prior to the measurement process illustrated in FIG. 4. As a substrate used in this process, a substrate for weighting prepared for deciding weighting may be used, or a substrate to be used in the process illustrated in FIG. 4 may be used. When the substrate to be used in the process illustrated in FIG. 4 is used in this process, this substrate can also be understood as the substrate for weighting. A weight decision sequence is executed by the control unit CU. Steps S501 to S505 shown in FIG. 6 are similar to steps S301 to S305 shown in FIG. 4, so that a description thereof will be omitted here.

In step S506, the control unit CU calculates the position of the substrate 73 based on pieces of position information of the marks 72A and 72B obtained in step S504 for all the sample regions set in advance. At this time, the position of the substrate 73 may be calculated by performing statistic processing using the position information acquired for one of at least two marks 72A and 72B. Alternatively, the same weight may be given to all of at least two marks 72A and 72B. Alternatively, a weight set as default or a weight used in past measurement may be set.

In step S507, based on the position of the substrate 73 calculated in step S506, a pattern is formed on the substrate 73. This pattern can include a device pattern and a measurement mark. Step S507 can be executed by a lithography apparatus incorporating the image capturing device 50. This execution can be controlled by the control unit CU.

In step S508, the position of the pattern formed on the substrate 73 in step S507 can be measured. Alternatively, in step S508, the relative position (overlay) between the pattern formed on the substrate 73 in step S507 and a pattern in a lower layer may be measured. Alternatively, in step S508, characteristic information including signal intensity information may be acquired by capturing, by the image capturing device 50, an image of the pattern formed on the substrate 73 in step S507.

Step S509 is a deciding step of deciding the weight based on the overlay error of each of the plurality of shot regions on the substrate for weight decision. More specifically, in step S509, based on the position of the pattern acquired in step S508, the control unit CU decides weights to be respectively given to at least two marks 72A and 72B. Thus, the weight decision sequence ends.

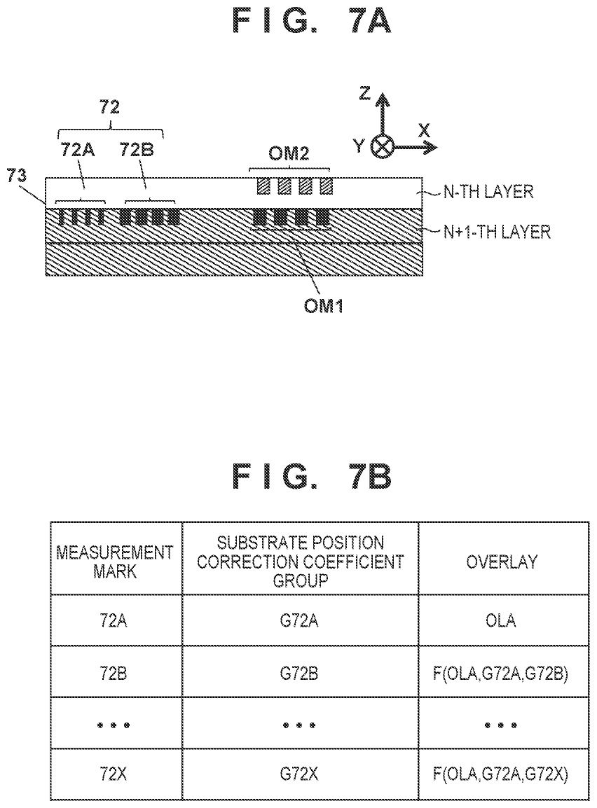

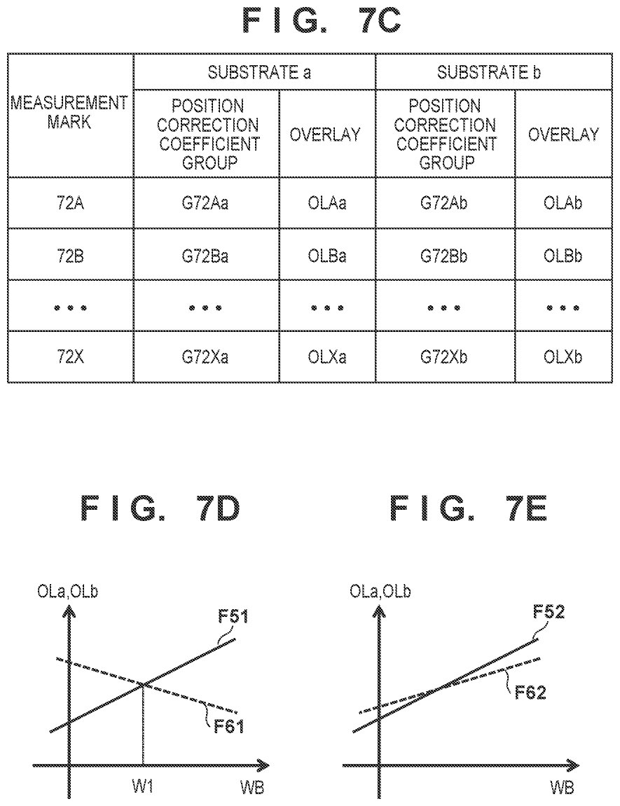

FIG. 7A is a view exemplarily showing the section structure of the measurement mark 72 and an overlay measurement mark on the substrate 73. An overlay measurement mark OM1 can be formed in the Nth layer of the substrate 73 together with the above-described measurement mark 72. For example, in step S507 of FIG. 6, an overlay measurement mark OM2 is formed in the (N+1)th layer of the substrate 73 based on the position measurement result of the measurement mark 72.

In step S508 of FIG. 6, when acquiring the position information of the pattern, for example, the position of the overlay measurement mark OM2 on the substrate 73 can be measured. Alternatively, the relative position between the overlay measurement marks OM1 and OM2 may be measured. By performing the above-described measurement on the plurality of shot regions on the substrate 73, for example, the position of the pattern in accordance with the positions of the plurality of shot regions on the substrate 73 can be acquired.

An example of the method of calculating the weight in step S509 of FIG. 6 is a method of calculating a weight based on the overlay error acquired in step S508. FIG. 7B is a table showing the relationship among the kind of at least two marks 72A, 72B, . . . , 72X, a position correction coefficient group of the substrate 73 based on the measurement values of at least two marks 72A, 72B, . . . , 72X, and the overlay error of the formed pattern. For example, a position correction coefficient group G72A of the substrate can be a result obtained by executing global alignment calculation based on the position measurement result of the mark 72A. The position correction coefficient group can specifically include the positional shift of the substrate, the magnification error, and the rotation error. An overlay error OLA can be acquired by forming a pattern on the substrate based on the position correction coefficient group G72A of the substrate, and evaluating the pattern by an overlay measuring device or the like. For example, the overlay error of the substrate includes the average value and variation of the overlay measurement values at a plurality of positions on the substrate.

An overlay error OLB in a case of executing substrate alignment based on the position measurement value of the mark 72B can be estimated by the following equation based on the position correction coefficient groups G72A and G72B of the substrate and the overlay error OLA.

$$OLB = F ( OLA , G 72 A , G 72 B ) \qquad ( 1 )$$

More specifically, for each position on the substrate where the overlay error is measured, the difference amount between position correction using the position correction coefficient group G72A of the substrate and position correction using the position correction coefficient group G72B of the substrate can be calculated. Then, the overlay error OLB can be calculated by performing calculation processing of adding the difference amount in position correction to the overlay error OLA.

In this embodiment, the position of the substrate is measured based on the images obtained by simultaneously capturing at least two marks 72A and 72B in the shot region by using the image capturing device 50. Then, each position correction coefficient group of the substrate is calculated based on the measurement value acquired for each of at least two marks 72A and 72B. Accordingly, the position correction coefficient group of the substrate corresponding to each of at least two marks 72A and 72B is calculated, and the overlay measurement value corresponding to each of at least two marks 72A and 72B can be estimated based on the position information of the pattern formed on the substrate.

The weight can be decided such that the overlay error, which is obtained based on evaluation values respectively obtained from images obtained by capturing a plurality of marks on the substrate for weight decision, that is, the overlay error of each of the plurality of shot regions, meets a target value. More preferably, the weight can be decided such that the overlay error, which is obtained based on evaluation values respectively obtained from images obtained by capturing a plurality of marks on the substrate for weight decision, that is, the overlay error of each of the plurality of shot regions, becomes minimum. With reference to FIG. 7C, a specific weight deciding method will be described below. FIG. 7C shows the position correction coefficient group and the overlay error for each of at least two marks 72A, 72B, . . . , 72X for two substrates a and b for weight decision. For example, a position correction coefficient group G72Aa and an overlay error OLAa are for the mark 72A on the substrate a, and a position correction coefficient group G72Ab and an overlay error OLAb are for the mark 72A on the substrate b. Overlay errors OLB to OLX are values estimated for the marks 72B to 72X, respectively, and calculated based on the measured overlay error OLA ad the position correction coefficient group G72A as has been described above.

Here, defining WA and WB be weights given to the marks 72A and 72B, respectively, the overlay errors OLa and OLb for the substrate a are expressed by:

$$OLa = OLAa \times WA + OLBa \times WB \qquad ( 2 )$$

$$OLb = OLAb \times WA + OLBb \times WB \qquad ( 3 )$$

When two marks of the marks 72A and 72B are used, the following relationship holds between the weights WA and WB.

$$WA + WB = 1 \qquad ( 4 )$$

By substituting equation (4) into each of equations (2) and (3) and

summarizing them, following equations (5) and (6) can be obtained.

$$OLa = ( OLBa - OLAa ) \times WB + OLAa \qquad ( 5 )$$

$$OLb = ( OLBb - OLAb ) \times WB + OLAb \qquad ( 6 )$$

FIG. 7D is a graph with the abscissa representing the weight WB given to the mark 72B, and the ordinate representing the overlay errors OLa and OLb. As expressed by equations (5) and (6), each of the overlay errors OLa and OLb is a function of WB. Therefore, in accordance with the magnitude relationship between OLBa and OLAa, OLa can be expressed as F51, and OLb can be expressed as F61. In this case, it can be seen that both the overlay errors OLa and OLb become small when the weight WB is equal to W1. Accordingly, the weights of the marks 72A and 72B can be set to be 1-W1 and W1, respectively. Similarly, by calculating weights of two marks different from each other, weights to be given to them can be decided. Thus, the weight that minimizes the overlay error can be decided.

Further, as shown in FIG. 7E, in a case of the overlay errors OLa and OLb expressed as F52 and F62, respectively, it can be seen that both the overlay errors OLa and OLb become small when the weight WB is set to 0. This means that measurement is performed without using the mark 72B. For example, a weight=1 may be set for one of at least two marks, and a weight=0 may be set for the other mark. Further, the weights to be given to at least two marks are not limited to be set to positive numbers, but may be set to negative numbers within a range satisfying equation (4).

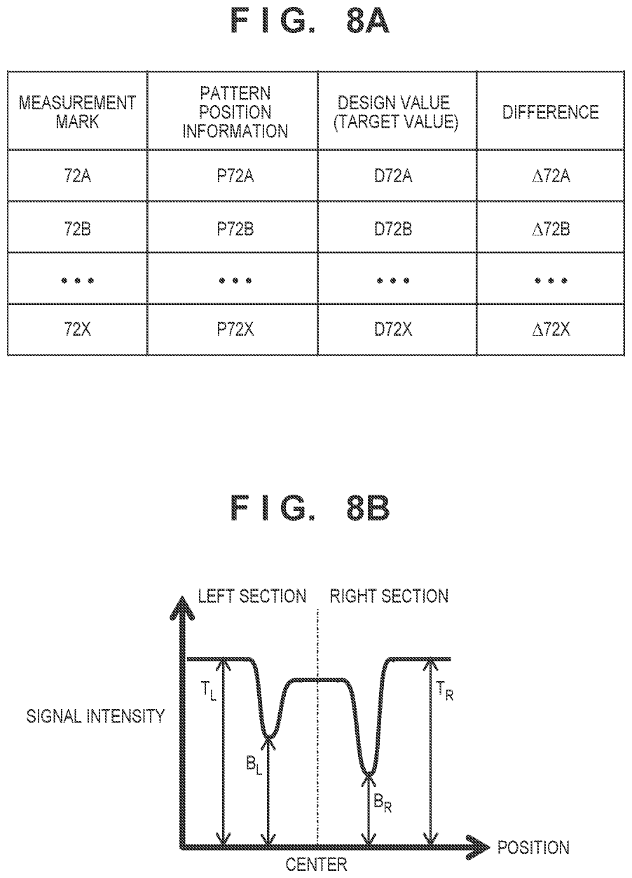

As another example of the weight deciding method, the weight may be decided based on the difference amount between the position information of the pattern acquired in step S508 of FIG. 6 and the target position information (for example, design value (target value)) such that, for example, the difference amount becomes minimum. FIG. 8A is a table showing the relationship between pieces of pattern position information P72A to P72X of at least two marks 72A to 72X and design values D72A to D72X. Each of differences Δ72A to Δ72X is a value obtained by calculating the difference between the pattern position information and the design value (target value) for each of the marks 72A to 72X. Note that each of the position information and measurement value of the pattern is not limited to one. For example, the average value or variation of the differences between pieces of position information of a plurality of patterns measured for the plurality of shot regions on the substrate and respective design values may be calculated. The weight can be decided such that the differences Δ72A to Δ72X become minimum. The weight may be calculated in a manner similar to that described using FIGS. 7C to 7E.

As still another method, the weight may be decided based on the signal intensity information of the pattern acquired in step S508 such that the intensity of the detection signal from the measurement mark 72 or the signal quality of the detection signal, which is one of evaluation values, for example, the contrast becomes maximum. Alternatively, the weight may be decided such that the asymmetry (another example of the signal quality) of the detection signal, which is one of evaluation values, becomes minimum. Further, the weight may be decided such that the variation of intensities of the detection signals or the variation of the evaluation index values in the plurality of shot regions on the substrate 73 become minimum.

Here, the evaluation index value of the detection signal is an index value indicating the quality of the detection signal from the pattern to be measured. The evaluation index value of the detection signal will be described below using FIG. 8B. FIG. 8B is a graph showing an example of the intensity information (signal intensity) of the detection signal from the pattern. The abscissa represents the position, and the ordinate represents the signal intensity. Due to the difference in the structure on the substrate between the pattern portion and the non-pattern portion, the signal intensity changes in accordance with the positions. An example of the evaluation index value is a value quantifying the asymmetry of the detection signal. For example, in FIG. 8B, let TL be the maximum value and BL be the minimum value of the signal intensity of the detection signal in the left section, let TR be the maximum value and BR be the minimum value of the signal intensity in the right section, and let ML and MR be the signal intensity of the detection signal in the central portion. In this case, as expressed by following equation (7), an asymmetry ES between the left section and right section of the detection signal may be obtained as characteristic information.

$$ES = ( TL - BL ) / ( TL + BL ) - ( TR - BR ) / ( TR + BR ) \qquad ( 7 )$$

The method of calculating the asymmetry is not limited to equation (7). For example, the center position of the detection signal may be defined, and the asymmetry of the detection signal may be calculated based on the signal intensity in a predetermined position range in each of the left section and the right section with respect to the center position. Alternatively, as another evaluation value, for example, the contrast of the measurement pattern may be evaluated as expressed by following equation (8).

$$EC = \{ ( TL ‐ BL ) / ( TL + BL ) + ( TR - BR ) / ( TR + BR ) \} / 2 \qquad ( 8 )$$

Here, in step S306 of FIG. 4, the weights given to at least two marks need not be the same in all the sample regions on the substrate 73. For example, the weights may be decided in accordance with the position of the sample region on the substrate 73. In addition, the weights need not be the same in the measurement directions on the substrate 73. For example, the weights may be decided in accordance with the measurement direction, that is, the X direction and the Y direction.

Next, correction of optical aberrations in this embodiment will be described. In a case in which the image capturing device 50 simultaneously detects at least two marks in the shot region, if optical aberrations (particularly, distortion) are large in the field of view of the image capturing device 50, errors occur in the measurement values of at least two marks. This can cause degradation of substrate measurement accuracy.

To prevent this, a correction amount (correction table) corresponding to the position in the field of view is created by obtaining, in advance, the error value caused by the optical aberrations in the image capturing device 50. As a method of creating the correction table, the measurement values corresponding to the positions in the field of view may be obtained using the same mark. Alternatively, the measurement values corresponding to the positions in the field of view may be obtained using a grid pattern.

In step S304 of FIG. 4, it is preferable to acquire position information of each of at least two marks in the shot region while correcting the measurement value of each mark by using the created correction table. With this, during measurement of the positions of at least two marks in the shot region, the error caused by the optical aberrations can be reduced.

### Second Embodiment

As the second embodiment, a measurement apparatus (mark monitor) that measures the characteristics of a measurement target object (for example, mark) will be described. First, functions of the measurement apparatus (mark monitor) will be described. In order to accurately align a substrate 73 and form a device pattern at a desired position, it is important to detect a change in characteristic information (shape, structure, physical property value, and the like) of the substrate. If the characteristic of the substrate changes more than expected, the measurement value of the mark changes, and the alignment accuracy of the substrate and the overlay accuracy of patterns on the substrate may deteriorate. Therefore, the characteristics of the mark are measured (monitored) to detect an abnormality in the substrate. With this, it is possible to take measures such as warning and error notification. The mark may be, for example, an alignment mark or an overlay measurement mark, or may be a device pattern.

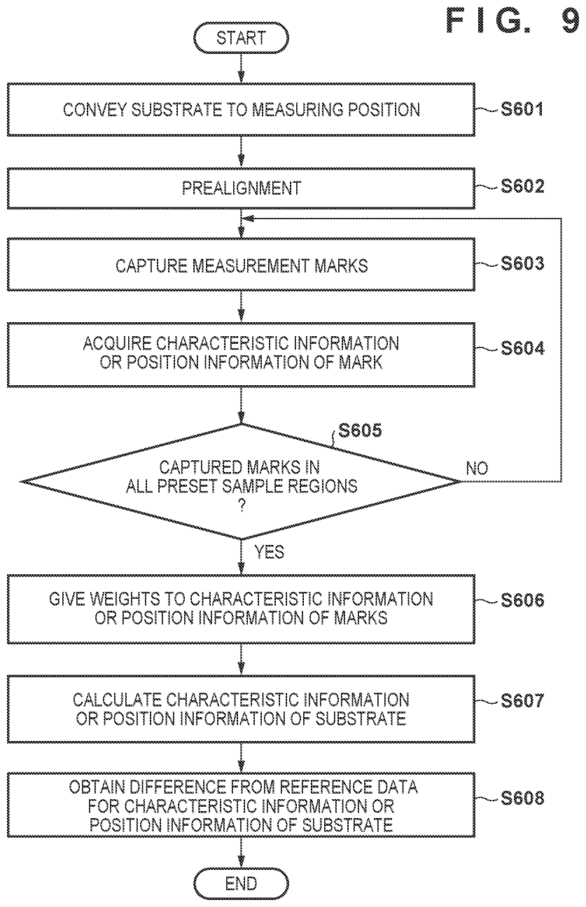

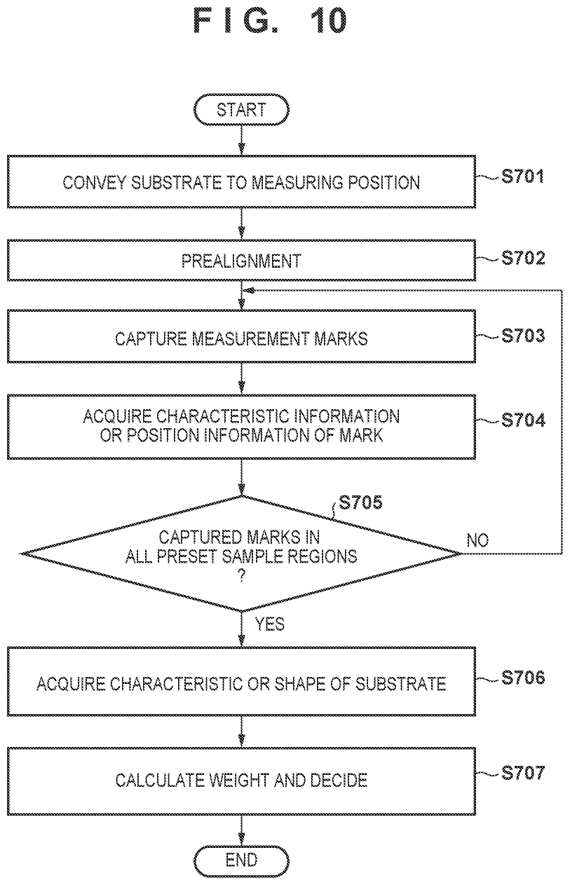

With reference to FIG. 9, a measuring method according to the second embodiment will be described below. The second embodiment is different from the first embodiment in that the characteristic information of the mark is acquired and then comparison and determination are performed, so that a part concerning this will be described below in detail. The remaining part is similar to that in the first embodiment, and a description thereof will be omitted here. Matters not mentioned here can follow the first embodiment.

FIG. 9 is a flowchart illustrating a measurement sequence in the second embodiment. After a measurement process is started, by steps S601 to S603, the substrate 73 is aligned such that at least two marks on the substrate fall within the field of view of an image capturing device 50, and images of at least two marks are captured. Then, by step S604, a control unit CU acquires characteristic information of each of at least two marks based on the images captured in step S603. The characteristic information of the mark can include at least one of, for example, the shape, structure, and physical property value of the substrate. The characteristic information of the mark can include, for example, the evaluation value (asymmetry or contrast) of a detection signal as given by equation (7).

In step S605, the control unit CU causes the image capturing device 50 to capture images of at least two marks in each of all sample regions set in advance with respect to the substrate 73. In step S606, the control unit CU gives weights decided in advance to the pieces of characteristic information of at least two marks acquired in each sample region in step S604. A method of calculating and setting the weights will be described later in detail. In step S607, the control unit CU calculates characteristic information or position information of the substrate based on the result of step S606. A specific calculation method will be described later in detail.

In step S608, the control unit CU obtains the difference between reference data and the physical property information or position information of the substrate calculated in step S607. Then, the control unit CU determines, for example, whether an allowable value (target value) is achieved. As the reference data, pieces of characteristic information or position information of a plurality of substrates obtained in advance may be used. As the allowable value, the variation amount of the plurality of substrates obtained in advance, the shape of the substrate required to achieve an overlay target, or the like may be set.

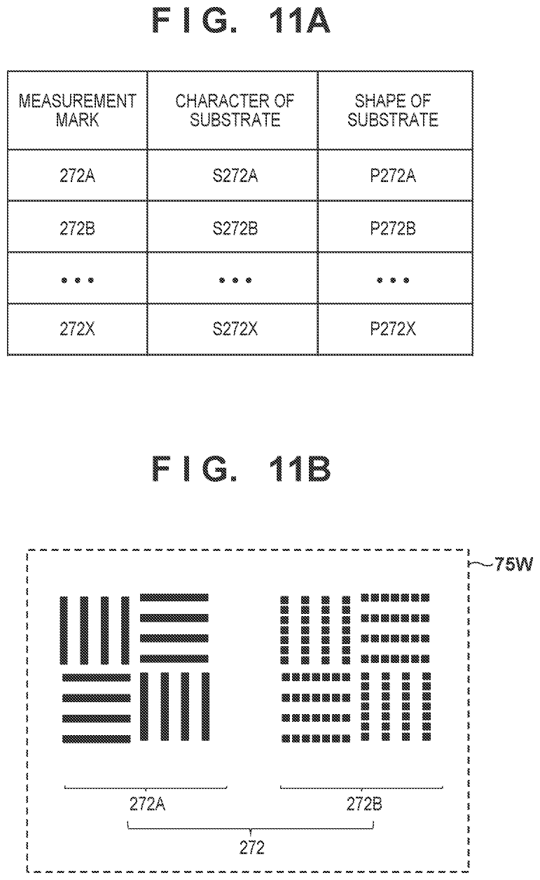

With reference to FIGS. 10 to 11B, a method of calculating and setting weights with respect to at least two marks will be described below. FIG. 10 is a flowchart illustrating a weight decision sequence in this embodiment. This process is preferably executed prior to the measurement process illustrated in FIG. 9.

By steps S701 to S703, a substrate for weighting is aligned such that at least two marks on the substrate for weighting fall within the field of view of the image capturing device 50, and images of at least two marks are captured. In step S704, the control unit CU acquires position information or characteristic information of each of at least two marks based on the images captured in step S703. In step S705, the control unit CU causes the image capturing device 50 to capture images of at least two marks in each of all sample regions set in advance with respect to the substrate for weighting.

In step S706, the control unit CU obtains the characteristic or shape of the substrate for weighting based on pieces of characteristic information or position information of marks acquired in step S704 for the plurality of sample regions on the substrate for weighting. For example, the characteristic of the substrate may be obtained by obtaining the average value of asymmetry or contrast, which is an evaluation value of the detection signal, of the plurality of sample regions. Alternatively, the characteristic of the substrate may be obtained by obtaining the variation of asymmetry or contrast, which is an evaluation value of the detection signal, of the plurality of sample regions. Further, the distortion shape of the substrate may be obtained based on measurement values of marks formed in the plurality of sample regions.

In step S707, based on the characteristic or shape of the substrate acquired in step S706, the control unit CU decides weights to be given respectively to at least two marks. Thus, the weight decision sequence ends.

A method of calculating a weight in the mark monitor according to the second embodiment will be described below. In order to accurately detect a change in characteristic of the substrate, it is preferable that the evaluation value of the detection signal of a mark sensitively changes with respect to the change in characteristic of the substrate.

FIG. 11A is a table showing the relationship among the kind of at least two marks and the characteristic and shape of the substrate obtained in step S706. For example, a characteristic S272A of the substrate indicates a value obtained based on characteristic information of a mark 272A in each of the plurality of sample regions on the substrate. A shape P272A of the substrate indicates a value obtained based on position information of the mark 272A in each of the plurality of sample regions on the substrate.

FIG. 11B is a view showing an example of the arrangement of a measurement mark 272 on the substrate. The measurement mark 272 includes at least two marks 272A and 272B. The mark 272B is a mark segmented in a non-measurement direction of a mark pattern as compared to the mark 272A. Note that at least two marks 272A and 272B are different from each other in at least one of the light width, pitch, and segmentation of the mark pattern, and the layer on the substrate where the mark is formed. The measurement mark 272 on the substrate is aligned with respect to a measurement region 75W of the image capturing device 50 on the substrate.

As one method of calculating the weight, weights to be given to at least two marks may be decided such that the variation of asymmetry or contrast of the detection signal becomes maximum in the plurality of sample regions on the substrate. Alternatively, weights to be given to at least two marks may be decided such that the distortion shape of the substrate becomes maximum.

As has been described above, in the second embodiment, based on images obtained by capturing at least two marks, characteristic information or position information of each of at least two marks is measured. The characteristic or position of the substrate is calculated in accordance with weighting from the pieces of characteristic information or position information of at least two marks. With this, it is possible to accurately detect a measurement target.

An information processing method of processing information acquired using the measurement apparatus described above will be exemplarily described. The information processing method is preferable to measure, for example, a measurement target object (alignment mark, overlay measurement mark, device pattern, or the like) on a substrate. The information processing method includes an image capturing step of capturing images of at least two marks formed on a substrate, and a measuring step of measuring signal intensity information or position information of each of at least two marks, by using the measurement apparatus 100. The information processing method can also include a calculation step of calculating, from the signal intensity information or position information of each of a plurality of marks, the characteristic or position of the substrate in accordance with weighting decided in advance. The information processing method can also include a decision step of deciding a weight to be given from the signal intensity information or position information of each of at least two marks. The information processing method in this embodiment can accurately detect a measurement target as compared to a prior art.

### Third Embodiment

The measurement apparatus 100 described above can be incorporated in a lithography apparatus. Such a lithography apparatus includes the measurement apparatus 100, and a system that aligns a substrate and an original based on a result obtained by the measurement apparatus 100 and transfers the pattern of the original to the substrate. The lithography apparatus can be, for example, an exposure apparatus or an imprint apparatus. The measuring method described above can be employed for a pattern forming method of forming a pattern on a substrate. Such a pattern forming method can include a measuring step of measuring a substrate by the measuring method described above, and a transfer step of transferring a pattern to the substrate based on a result obtained in the measuring step. The pattern forming method can further be employed for an article manufacturing method. Such an article manufacturing method can include a pattern forming step of forming a pattern on a substrate in accordance with the pattern forming method, and a processing step of obtaining an article by processing the substrate with the pattern formed thereon in the pattern forming step.

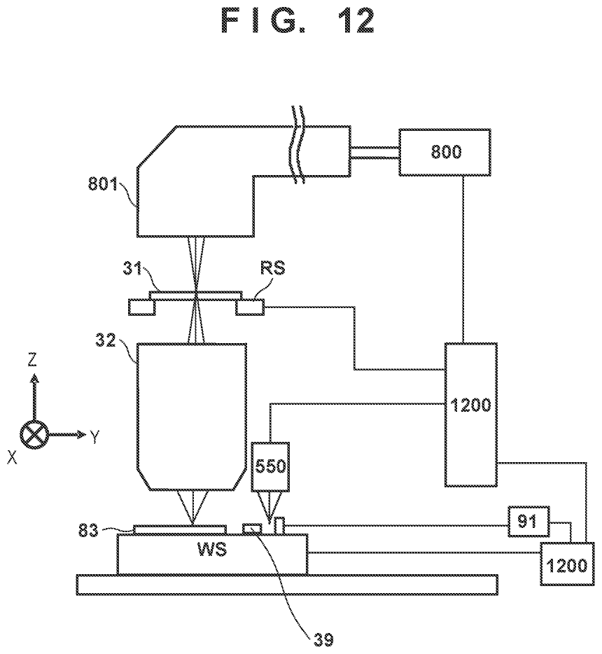

FIG. 12 is a schematic view showing the arrangement of an exposure apparatus EXA. The exposure apparatus EXA is a lithography apparatus which is used in a lithography process as a manufacturing process of a device such as a semiconductor device or a liquid crystal display device and forms a pattern on a substrate 83. The exposure apparatus EXA exposes the substrate 83 via a reticle 31 serving as an original, thereby transferring the pattern of the reticle 31 to the substrate 83. In this embodiment, the exposure apparatus EXA employs a step-and-scan method, but it can also employ a step-and-repeat method or other exposure methods.

As shown in FIG. 12, the exposure apparatus EXA includes an illumination optical system 801, a reticle stage RS which holds the reticle 31, a projection optical system 32, a substrate stage WS which holds the substrate 83, a position measurement apparatus 550, and a control unit 1200.

The illumination optical system 801 is an optical system that illuminates an illuminated surface using light from a light source unit 800. The light source unit 800 includes, for example, a laser. The laser includes an Arf excimer laser having a wavelength of about 193 nm, a KrF excimer laser having a wavelength of about 248 nm, or the like, but the type of light source is not limited to the excimer laser. For example, the light source unit 800 may use, as the light source, an F2 laser having a wavelength of about 157 nm or Extreme Ultraviolet (EUV) having a wavelength of 20 nm or less.

In this embodiment, the illumination optical system 801 shapes the light from the light source unit 800 into slit light having a predetermined shape suitable for exposure, and illuminates the reticle 31. The illumination optical system 801 has a function of uniformly illuminating the reticle 31 and a polarizing illumination function. The illumination optical system 801 includes, for example, a lens, a mirror, an optical integrator, a stop, and the like, and is formed by arranging a condenser lens, a fly-eye lens, an aperture stop, a condenser lens, a slit, and an imaging optical system in this order.

The reticle 31 is formed of, for example, quartz. The reticle 31 is formed with a pattern (circuit pattern) to be transferred to the substrate 83.

The reticle stage RS holds the reticle 31 via a reticle chuck (not shown), and is connected to a reticle driving mechanism (not shown). The reticle driving mechanism includes a linear motor or the like, and can move the reticle 31 held by the reticle stage RS by driving the reticle stage RS in the X-axis direction, the Y-axis direction, the Z-axis direction, and the rotation directions around the respective axes. Note that the position of the reticle 31 is measured by a reticle position measuring unit of light oblique-incidence type (not shown), and the reticle 31 is arranged at a predetermined position via the reticle stage RS.

The projection optical system 32 has a function of imaging the light from an object plane in an image plane. In this embodiment, the projection optical system 32 projects the light (diffracted light) having passed through the pattern of the reticle 31 onto the substrate 83, thereby forming the image of the pattern of the reticle 31 on the substrate. As the projection optical system 32, an optical system formed from a plurality of lens elements, an optical system (catadioptric optical system) including a plurality of lens elements and at least one concave mirror, an optical system including a plurality of lens elements and at least one diffractive optical element such as kinoform, or the like is used.

A photoresist is applied onto the substrate 83. The substrate 83 is a processing target object to which the pattern of the reticle 31 is transferred, and can include a wafer, a liquid crystal substrate, another member, or the like.

The substrate stage WS holds the substrate 83 via a substrate chuck (not shown), and is connected to a substrate driving mechanism (not shown). The substrate driving mechanism includes a linear motor or the like, and can move the substrate 83 held by the substrate stage WS by driving the substrate stage WS in the X-axis direction, the Y-axis direction, the Z-axis direction, and the rotation directions around the respective axes. Further, a reference plate 39 is provided on the substrate stage WS.

The position of the reticle stage RS and the position of the substrate stage WS are monitored by, for example, a 6-axis laser interferometer 91 or the like, and the reticle stage RS and the substrate stage WS are driven at a constant speed ratio under the control of the control unit 1200.

The control unit 1200 is formed by a computer (information processing apparatus) including a CPU, a memory, and the like and, for example, operates the exposure apparatus EXA by comprehensively controlling respective units of the exposure apparatus EXA in accordance with a program stored in a storage unit. The control unit 1200 controls an exposure process of transferring the pattern of the reticle 31 to the substrate 83 by exposing the substrate 83 via the reticle 31. Further, in this embodiment, the control unit 1200 controls a measurement process in the position measurement apparatus 550 and a correction process (calculation processing) of a measurement value obtained by the position measurement apparatus 550. In this manner, the control unit 1200 also functions as a part of the position measurement apparatus 550.

In the exposure apparatus EXA, the light (diffracted light) having passed through the reticle 31 is projected onto the substrate 83 via the projection optical system 32. The reticle 31 and the substrate 83 are arranged in an optically conjugate relationship. The pattern of the reticle 31 is transferred to the substrate 83 by scanning the reticle 31 and the substrate 83 at a speed ratio of a reduction ratio of the projection optical system 32.

The position measurement apparatus 550 is a measurement apparatus for measuring the position of a target object. The measurement apparatus 100 described above can be employed as the position measurement apparatus 550. In this embodiment, the position measurement apparatus 550 measures the positions of a plurality of marks 82 such as alignment marks provided on the substrate 83. Note that the arrangement of the position measurement apparatus 550 is similar to the arrangement of the image capturing device 50 shown in FIG. 1B, so that a description thereof will be omitted here.

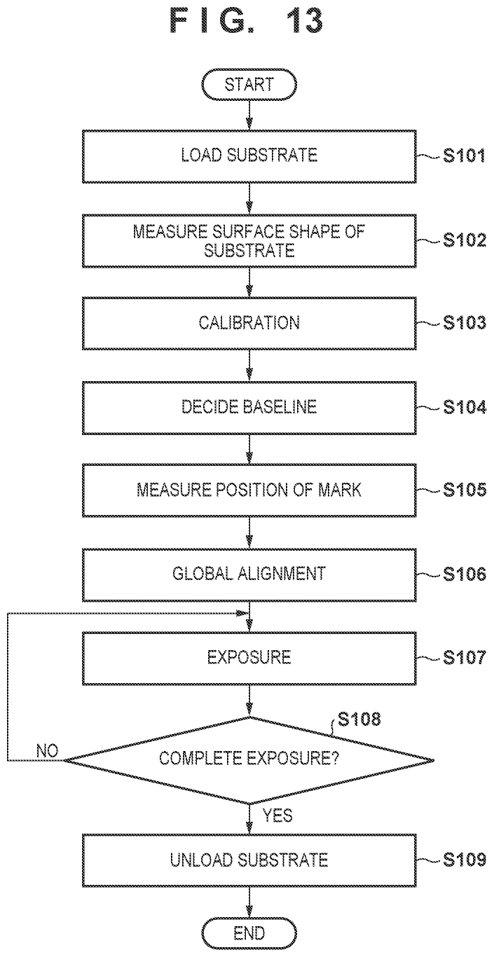

With reference to FIG. 13, the sequence of an exposure process of transferring the pattern of the reticle 31 onto the substrate 83 by exposing the substrate 83 via the reticle 31 will be described. As has been described above, the exposure process is performed by the control unit 1200 comprehensively controlling the respective units of the exposure apparatus EXA.

In step S101, the substrate 83 is loaded in the exposure apparatus EXA. In step S102, the surface (height) of the substrate 83 is detected by a shape measurement apparatus (not shown) to measure the surface shape of the entire substrate 83.

In step S103, calibration is performed. More specifically, based on the designed coordinate position of the reference mark provided in the reference plate 39 in the stage coordinate system, the substrate stage WS is driven so as to position the reference mark on the optical axis of the position measurement apparatus 550. Then, the positional shift of the reference mark with respect to the optical axis of the position measurement apparatus 550 is measured, and the stage coordinate system is reset based on the positional shift such that the origin of the stage coordinate system coincides with the optical axis of the position measurement apparatus 550. Next, based on the designed positional relationship between the optical axis of the position measurement apparatus 550 and the optical axis of the projection optical system 32, the substrate stage WS is driven so as to position the reference mark on the optical axis of the exposure light. Then, the positional shift of the reference mark with respect to the optical axis of the exposure light is measured via the projection optical system 32 by a TTL (Through The Lens) measurement system.

In step S104, based on the result of calibration obtained in step S103, the baseline between the optical axis of the position measurement apparatus 550 and the optical axis of the projection optical system 32 is determined. In step S105, the position measurement apparatus 550 measures the position of the mark 82 provided on the substrate 83.

In step S106, global alignment is performed. More specifically, based on the measurement result obtained in step S105, the shift, the magnification, and the rotation with respect to the array of shot regions on the substrate 83 are calculated, and the regularity of the array of the shot regions is obtained. Then, a correction coefficient is obtained from the regularity of the array of the shot regions and the baseline, and the substrate 83 is aligned with the reticle 31 (exposure light) based on the correction coefficient.

In step S107, the substrate 83 is exposed while scanning the reticle 31 and the substrate 83 in a scanning direction (Y direction). At this time, based on the surface shape of the substrate 83 measured by the shape measurement apparatus, an operation of sequentially adjusting the surface of the substrate 83 to the imaging plane of the projection optical system 32 is also performed by driving the substrate stage WS in the Z direction and the tilt direction.

In step S108, it is determined whether exposure for all the shot regions of the substrate 83 is completed (that is, whether there is no unexposed shot region). If exposure for all the shot regions of the substrate 83 is not completed, the process returns to step S107, and steps S107 and S108 are repeated until exposure for all the shot regions is completed. On the other hand, if exposure for all the shot regions of the substrate 83 is completed, the process advances to step S109, and the substrate 83 is unloaded from the exposure apparatus EXA.

In this embodiment, an image of light from each of a plurality of marks different from each other is captured, an image capturing region is set for each mark, and position information for each of the plurality of marks different from each other is measured. The position of the substrate is calculated in accordance with weighting from the pieces of position information of the plurality of marks different from each other. With this, it is possible to accurately measure a measurement target.

An article manufacturing method of manufacturing an article by using the above lithography apparatus will be exemplarily described. The article manufacturing method is suitable for, for example, manufacturing an article such as a device (a semiconductor device, a magnetic storage medium, a liquid crystal display device, or the like). The manufacturing method includes a step of exposing, by using the exposure apparatus EXA, a substrate with a photosensitive agent applied thereon (forming a pattern on the substrate), and a step of developing the exposed substrate (processing the substrate). In addition, the manufacturing method can include other well-known steps (oxidation, film formation, deposition, doping, planarization, etching, resist removal, dicing, bonding, packaging, and the like). The article manufacturing method of this embodiment is more advantageous than the conventional methods in at least one of the performance, quality, productivity, and production cost of the article. Note that the above-described article manufacturing method may be performed by using a lithography apparatus such as an imprint apparatus or a drawing apparatus.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-030137, filed Feb. 28, 2023, which is hereby incorporated by reference herein in its entirety.

What is claimed is:

1. A measuring method of measuring a substrate, comprising:
capturing images of a plurality of marks provided on the substrate; and
processing a plurality of evaluation values while giving weights to the plurality of evaluation values respectively obtained from the images of the plurality of marks captured in the capturing, thereby acquiring information indicating a state of the substrate,
wherein the plurality of marks include at least two marks simultaneously captured in the capturing.

2. The method according to claim 1, wherein
in the processing, weights different from each other are given to evaluation values respectively obtained from images of the at least two marks.

3. The method according to claim 1, wherein
the substrate includes a first shot region and a second shot region, and
the plurality of marks include at least two marks arranged in the first shot region and at least two marks arranged in the second shot region.

4. The method according to claim 3, wherein
the at least two marks arranged in the first shot region are simultaneously captured in the capturing, and the at least two marks arranged in the second shot region are simultaneously captured in the capturing.

5. The method according to claim 4, wherein
in the processing, weights different from each other are given to evaluation values respectively obtained from images of the at least two marks arranged in the first shot region, and weights different from each other are given to evaluation values respectively obtained from images of the at least two marks arranged in the second shot region.

6. The method according to claim 3, wherein
the at least two marks arranged in the first shot region are brought into a field of view of one image capturing device in the capturing, and the at least two marks arranged in the second shot region are brought into the field of view in the capturing.

7. The method according to claim 6, wherein
in the processing, weights different from each other are given to evaluation values respectively obtained from images of the at least two marks arranged in the first shot region, and weights different from each other are given to evaluation values respectively obtained from images of the at least two marks arranged in the second shot region.

8. The method according to claim 1, wherein
the substrate includes a plurality of shot regions, and
in each of the plurality of shot regions, at least two marks are arranged.

9. The method according to claim 8, wherein
in the processing, weights different from each other are given to evaluation values respectively obtained from images of the at least two marks in each shot region.

10. The method according to claim 8, further comprising
deciding the weight based on an overlay error of each of a plurality of shot regions on a substrate for weight decision.

11. The method according to claim 10, wherein
in the deciding, the weight is decided such that the overlay error of each of the plurality of shot regions, which is obtained based on evaluation values respectively obtained from images obtained by capturing a plurality of marks in the substrate for weight decision, meets a target value.

12. The method according to claim 10, wherein
in the deciding, the weight is decided such that the overlay error of each of the plurality of shot regions, which is obtained based on evaluation values respectively obtained from images obtained by capturing a plurality of marks in the substrate for weight decision, becomes minimum.

13. The method according to claim 10, wherein
in the deciding, the weight is decided based on a difference between target position information and position information serving as an evaluation value obtained from each of images obtained by capturing a plurality of marks in the substrate for weight decision.

14. The method according to claim 10, wherein
in the deciding, the weight is decided based on a signal quality serving as an evaluation value obtained from each of images obtained by capturing a plurality of marks in the substrate for weight decision.

15. A pattern forming method of forming a pattern on a substrate, comprising:
measuring the substrate by a measuring method defined in claim 1; and
transferring a pattern to the substrate based on a result obtained in the measuring.

16. An article manufacturing method including:
forming a pattern on a substrate in accordance with a pattern forming method defined in claim 15; and
processing the substrate with the pattern formed thereon in the forming, thereby obtaining an article.

17. A measurement apparatus for measuring a substrate, comprising:
an image capturing device configured to capture images of a plurality of marks provided on the substrate; and
a processor configured to process a plurality of evaluation values while giving weights to the plurality of evaluation values respectively obtained from the images of the plurality of marks captured by the image capturing device, thereby acquiring information indicating a state of the substrate,
wherein the plurality of marks include at least two marks simultaneously captured by the image capturing device.

18. A lithography apparatus comprising:
a measurement apparatus defined in claim 17; and
a system configured to align a substrate and an original based on a result obtained by the measurement apparatus, and transfer a pattern of the original to the substrate.

19. An article manufacturing method comprising:
forming a pattern on a substrate by using a lithography apparatus defined in claim 18; and
processing the substrate with the pattern formed thereon in the forming, thereby obtaining an article.

20. A non-transitory computer readable medium storing a program for causing a computer to execute a process of evaluating a substrate, wherein
the process includes acquiring information indicating a state of the substrate by processing a plurality of evaluation values while giving weights to the plurality of evaluation values respectively obtained from images of the plurality of marks provided on the substrate,
wherein the plurality of marks include at least two marks captured simultaneously.
